(19) United States
(12) Patent Application Publication
(10) Pub. No.: US 2019/0318985 A1
(43) Pub. Date: Oct. 17, 2019

(54) PACKAGE STRUCTURE FOR ELECTRONIC ASSEMBLIES

(71) Applicant: National Taiwan Normal University, Taipei (TW)

(72) Inventor: Jung-Hsuan CHEN, Taipei (TW)

(21) Appl. No.: 16/006,041

(22) Filed: Jun. 12, 2018

(30) Foreign Application Priority Data
Apr. 17, 2018 (TW) 107113089

(51) Int. Cl. H01L 23/498; H01L 23/00; H05K 1/14; H01L 23/15; H01L 23/14; H05K 1/11; H05K 1/03

(52) U.S. Cl. CPC H01L 23/49827; H05K 2201/10734; H01L 24/16; H05K 1/144; H01L 24/17; H01L 23/15; H01L 23/145; H01L 24/13; H05K 1/115; H05K 1/0306; H05K 1/0313; H01L 2224/13111; H01L 2224/16235; H01L 2224/16054; H01L 2224/13147; H01L 2224/13155; H01L 2224/13124; H01L 2924/3841; H01L 2224/16055; H05K 2201/0116; H05K 2201/0154; H05K 2201/041; H05K 2201/10378; H05K 2201/10545; H01L 23/49838

(57) ABSTRACT

A package structure for electronic assemblies includes a porous insulation substrate, a conductive material, a first electronic assembly, and a second electronic assembly. The porous insulation substrate is penetrated with a plurality of through holes, and each of the plurality of through holes has a diameter which is larger than 0 and less than 1 um. The conductive material fills the plurality of through holes. The first electronic assembly is arranged under the porous insulation substrate and electrically connected to the conductive material in the plurality of through holes through at least one first conductive bump. The second electronic assembly is arranged over the porous insulation substrate and electrically connected to the conductive material in the plurality of through holes through at least one second conductive bump to electrically connect to the first electronic assembly.

This application claims priority for Taiwan patent application no. 107113089 filed on Apr. 17, 2018, the content of which is incorporated by reference in its entirety.

### BACKGROUND OF THE INVENTION

### Field of the Invention

The present invention relates to a package structure, particularly to a package structure for electronic assemblies.

### Description of the Related Art

Semiconductor devices are used in various electronic devices, such as personal computers, smart phones, digital cameras, and other electronic equipment. In order to fabricate a semiconductor device, an insulation layer, a dielectric layer, a conductive layer, and a semiconductor layer are sequentially deposited on a semiconductor substrate, and all the layers are patterned using a lithography process to form circuits and assemblies on the semiconductor substrate. Many integrated circuits (ICs) are fabricated on a single semiconductor wafer. The wafer is cut along cutting lines among the ICs to form many dies. For example, each die is packaged in a multi-chip module or other type of a package structure.

In a package structure, a first chip 10 is provided with a plurality of first conductive pads 12 thereon, and a second chip 14 is provided with a plurality of second conductive pads 16 thereon. The first conductive pads 12 are electrically connected to the second conductive pads 16 through solder bumps 18, whereby the first chip 10 is electrically connected to the second chip 14. However, in an advanced process, a solder bridge is easily formed when a gap between the solder bumps 18 is smaller, thereby causing a short. Besides, since one first conductive pad 12 is electrically connected to one second conductive pad 16 through one solder bump 18, the non-wetting and cold jointing of solder easily occurs to reduce the fabrication yield when the welding technique is bad.

To overcome the abovementioned problems, the present invention provides a package structure for electronic assemblies, so as to solve the afore-mentioned problems of the prior art.

### SUMMARY OF THE INVENTION

The primary objective of the present invention is to provide a package structure for electronic assemblies, which uses a porous insulation substrate to limit the flowing and deformation of solder and to greatly reduce the probability of bridging solder. In addition, one conductive bump is connected to solder in several hundreds of through holes to reduce the probabilities of non-wetting and cold jointing of solder and the fabrication cost and increase the fabrication yield.

To achieve the abovementioned objectives, the present invention provides a package structure for electronic assemblies, which comprises a porous insulation substrate, a conductive material, a first electronic assembly, and a second electronic assembly. The porous insulation substrate is penetrated with a plurality of through holes, and each of the plurality of through holes has a diameter which is larger than 0 and less than 1 um. The conductive material fills the plurality of through holes. The first electronic assembly is arranged under the porous insulation substrate and electrically connected to the conductive material in the plurality of through holes through at least one first conductive bump. The second electronic assembly is arranged over the porous insulation substrate and electrically connected to the conductive material in the plurality of through holes through at least one second conductive bump to electrically connect to the first electronic assembly.

In an embodiment of the present invention, the conductive material comprises solder. For example, the solder comprises a tin-included metal with a low melting point, a tin-included alloy, or a metallic composite material including tin.

In an embodiment of the present invention, the plurality of through holes further comprise several hundreds of through holes.

In an embodiment of the present invention, the first conductive bump and the second conductive bump have shapes of squares or circles. The first conductive bump and the second conductive bump comprise copper, aluminum, nickel, or a tin-included metal with a low melting point.

In an embodiment of the present invention, there are a plurality of first conductive bumps, and each of the plurality of first conductive bumps is electrically connected to the conductive material in several hundreds of the plurality of through holes.

In an embodiment of the present invention, there are a plurality of second conductive bumps, and each of the plurality of second conductive bumps is electrically connected to the conductive material in several hundreds of the plurality of through holes.

In an embodiment of the present invention, the porous insulation substrate comprises aluminum oxide, silicon dioxide, poly(methyl methacrylate) (PMMA), polycarbonate (PC), or polyimide (PI).

In an embodiment of the present invention, the first electronic assembly or the second electronic assembly is selected from a printed circuit board, an interposer, or an electronic chip.

Below, the embodiments are described in detail in cooperation with the drawings to make easily understood the technical contents, characteristics and accomplishments of the present invention.

### BRIEF DESCRIPTION OF THE DRAWINGS

FIG. 1 is a cross-sectional view of a package structure in the conventional technology;

FIG. 2 is a diagram showing a package structure for electronic assemblies according to the first embodiment of the present invention;

FIG. 3 is an exploded view of a package structure for electronic assemblies according to the first embodiment of the present invention;

FIG. 4 is a diagram showing a package structure for electronic assemblies according to the second embodiment of the present invention; and

FIG. 5 is an exploded view of a package structure for electronic assemblies according to the second embodiment of the present invention.

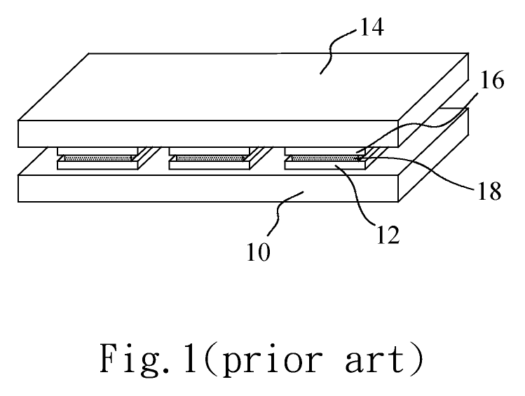

### DETAILED DESCRIPTION OF THE INVENTION

Reference will now be made in detail to embodiments illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, methods and apparatus in accordance with the present disclosure. It is to be understood that elements not specifically shown or described may take various forms well known to those skilled in the art. Many alternatives and modifications will be apparent to those skilled in the art, once informed by the present disclosure.

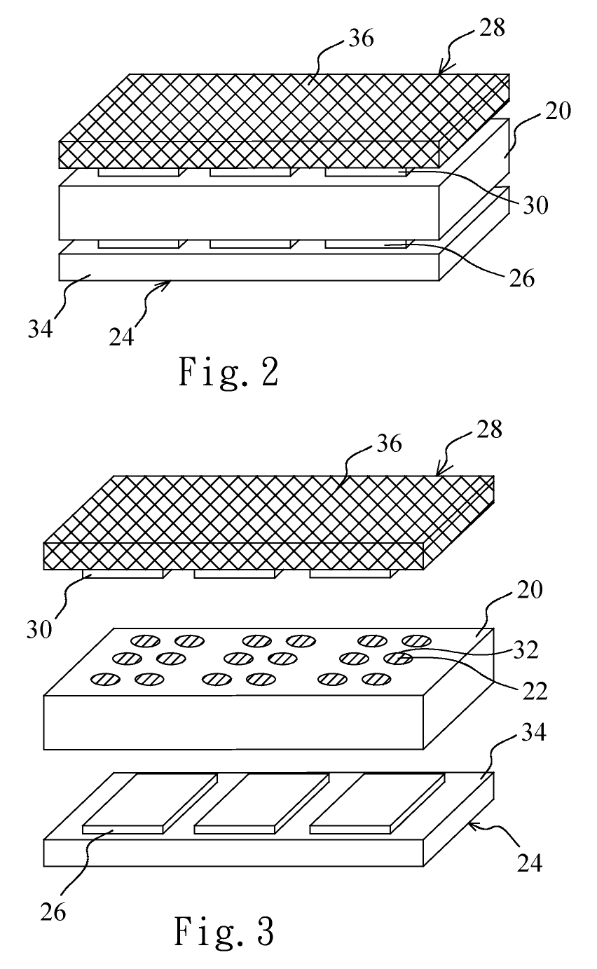

Refer to FIG. 2 and FIG. 3. The first embodiment of the package structure for electronic assemblies is introduced as follows. The package structure for electronic assemblies comprises a porous insulation substrate 20, a conductive material 22, a first electronic assembly 24, at least one first conductive bump 26, a second electronic assembly 28, and at least one second conductive bump 30. The porous insulation substrate 20 comprises aluminum oxide, silicon dioxide, poly(methyl methacrylate) (PMMA), polycarbonate (PC), or polyimide (PI). The conductive material 22 may be solder, such as a tin-included metal with a low melting point, a tin-included alloy, or a metallic composite material including tin. The metallic composite material includes metal and nonmetal materials, wherein the percentage of metal is higher than that of nonmetal materials. The nonmetal materials are used to enhance properties of the metal, such as a conductive property, a heat-dissipating property, or a mechanical property. The first conductive bump 26 and the second conductive bump 30 have shapes of squares or circles. The first conductive bump 26 and the second conductive bump 30 comprise copper, aluminum, nickel, or a tin-included metal with a low melting point. The porous insulation substrate 20 has a thickness of 0.5-200 um. The porous insulation substrate 20 is penetrated with a plurality of through holes 32, and each of the plurality of through holes 32 has a diameter which is larger than 0 and less than 1 um. The conductive material 22 fills all the through holes 32. The porous insulation substrate 20 limits the flowing and deformation of solder to greatly reduce the probability of bridging solder. The first electronic assembly 24 is arranged under the porous insulation substrate 20 and electrically connected to the conductive material 22 in the plurality of through holes 32 through the first conductive bump 26. The second electronic assembly 28 is arranged over the porous insulation substrate 20 and electrically connected to the conductive material 22 in the plurality of through holes 32 through the second conductive bump 30 to electrically connect to the first electronic assembly 24. For example, there are one first conductive bump 26, one second conductive bump 30, and several hundreds of through holes 32. In the first embodiment, there is a plurality of first conductive bumps 26, each of the plurality of first conductive bumps 26 is electrically connected to the conductive material 22 in several hundreds of the plurality of through holes 32, there is a plurality of second conductive bumps 30, and each of the plurality of second conductive bumps 30 is electrically connected to the conductive material 22 in several hundreds of the plurality of through holes 32. In other words, the size of the conductive bump is greatly lager than the size of the through hole 32. As a result, one conductive bump is electrically connected to the solder in several hundreds of through holes 32 to reduce the probabilities of non-wetting and cold jointing of solder and the fabrication cost and increase the fabrication yield. Since the solder is arranged in the porous insulation substrate 20 and the porous insulation substrate 20 has a fixed thickness and mechanical strength, the conductive bumps can reduce the height and save materials required.

The first electronic assembly 24 or the second electronic assembly 28 is selected from a printed circuit board, an interposer, or an electronic chip. In the first embodiment, the first electronic assembly 24 and the second electronic assembly 28 are respectively exemplified by a printed circuit board 34 and an interposer 36.

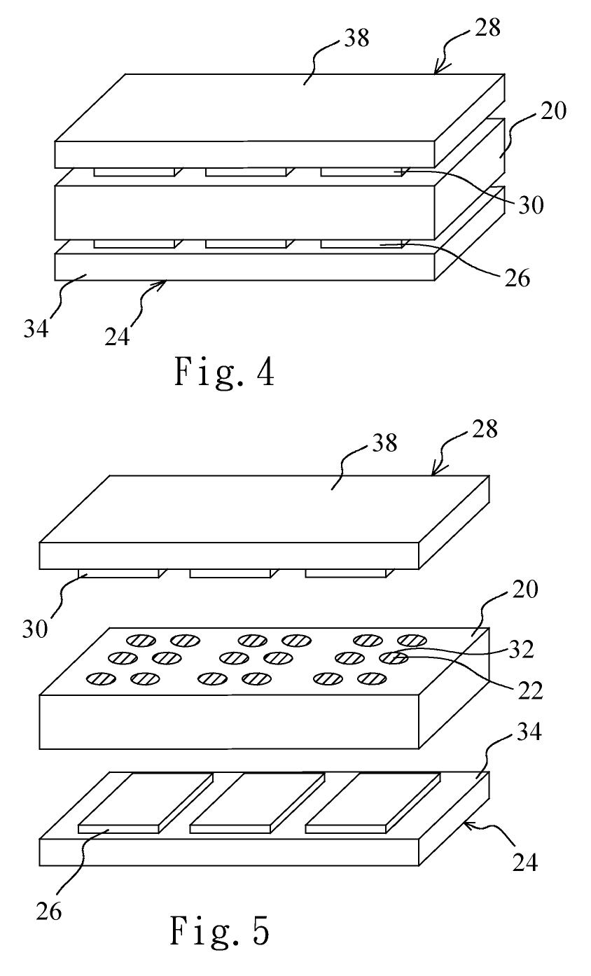

Refer to FIG. 4 and FIG. 5. The second embodiment of the package structure for electronic assemblies is introduced as follows. The structure of the first embodiment is identical to that of the second embodiment so will not be reiterated. The second embodiment is different from the first embodiment in the second electronic assembly 28. In the second embodiment, the second electronic assembly 28 is exemplified by an electronic chip.

In conclusion, the present invention uses the porous insulation substrate to limit the flowing and deformation of solder and to greatly reduce the probability of bridging solder. In addition, one conductive bump is connected to solder in several hundreds of through holes to reduce the probabilities of non-wetting and cold jointing of solder and the fabrication cost and increase the fabrication yield.

The embodiments described above are only to exemplify the present invention but not to limit the scope of the present invention. Therefore, any equivalent modification or variation according to the shapes, structures, features, or spirit disclosed by the present invention is to be also included within the scope of the present invention.

1. A package structure for electronic assemblies comprising:
a porous insulation substrate penetrated with a plurality of through holes, and each of the plurality of through holes has a diameter which is larger than 0 and less than 1 um and each of the plurality of through holes is arranged in the porous insulation substrate at a same height;
a conductive material filling the plurality of through holes;
a first electronic assembly arranged under the porous insulation substrate and electrically connected to the conductive material in the plurality of through holes through at least one first conductive bump; and
a second electronic assembly arranged over the porous insulation substrate and electrically connected to the conductive material in the plurality of through holes through at least one second conductive bump to electrically connect to the first electronic assembly,
wherein the at least one first conductive bump further comprises a plurality of first conductive bumps, and each of the plurality of first conductive bumps is electrically connected to the conductive material in several hundreds of the plurality of through holes, and
wherein the at least one second conductive bump further comprises a plurality of second conductive bumps, and each of the plurality of second conductive bumps is electrically connected to the conductive material in several hundreds of the plurality of through holes
wherein each of the plurality of first conductive bumps and each of the plurality of second conductive bumps respectively cover at least two of the plurality of through holes.

2. The package structure for electronic assemblies according to claim 1, wherein the conductive material comprises solder.

3. The package structure for electronic assemblies according to claim 2, wherein the solder comprises a tin-included metal with a low melting point, a tin-included alloy, or a metallic composite material including tin.

4. The package structure for electronic assemblies according to claim 1, wherein the at least one first conductive bump and the at least one second conductive bump have shapes of squares or circles.

5. The package structure for electronic assemblies according to claim 1, wherein the at least one first conductive bump and the at least one second conductive bump comprise copper, aluminum, nickel, or a tin-included metal with a low melting point.

6. The package structure for electronic assemblies according to claim 1, wherein the plurality of through holes further comprise several hundreds of through holes.

7. (canceled)

8. (canceled)

9. The package structure for electronic assemblies according to claim 1, wherein the porous insulation substrate comprises aluminum oxide, silicon dioxide, poly (methyl methacrylate) (PMMA), polycarbonate (PC), or polyimide (PI).

10. The package structure for electronic assemblies according to claim 1, wherein the first electronic assembly or the second electronic assembly is selected from a printed circuit board, an interposer, or an electronic chip.
